(19) United States
(12) Patent Application Publication
(10) Pub. No.: US 2007/0022333 A1
(43) Pub. Date: Jan. 25, 2007

(54) Testing of interconnects associated with memory cards

(76) Inventor: Steven W. Terry, Irving, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/155,171

(22) Filed: Jun. 17, 2005

(51) Int. Cl. G11C 29/00

(52) U.S. Cl. 714/718

(57) ABSTRACT

Various systems and method for testing data interconnects are provided. In one method, a test data value is transmitted from an interconnect test tool to a memory card included in a memory card bank through a first set of interconnects. A received data value received by the memory card is relayed through the first set of interconnects to a second set of interconnects. A return data value is received in the interconnect test tool from the memory card via the second set of interconnects. Finally, the existence of a defect is detected in one of the interconnects based upon the test data value and the return data value.

### BACKGROUND

The use of memory cards in processor based systems is commonplace in the computing world. In some large scale processing systems, many memory cards may be employed simultaneously and may be coupled to a so called “cell” or processor board. Such memory cards may be, for example, Dual Inline Memory Modules (DIMMs) or other types of memory cards. For example, in one large processor based system, it is not unheard of that multiple memory cards may be employed. For example, large banks of memory cards may be coupled to a processing system that may include over a thousand or more memory cards.

In order to access the memory on the memory cards, memory controllers may be employed to issue various control information to the memory cards. In order to facilitate communication with memory cards, a processor based system may include a cell board or other circuit board that includes connectors to facilitate the installation of other memory cards. The memory cards may include contacts that mate with contacts within the connectors. In one typical connection, memory cards include contacts on an edge that acts like a plug that slides into connectors on a cell board and is latched into place, thereby presumably establishing good electrical contact between the respective contacts of the respective memory card and the connector.

Unfortunately, it is not always the case that good electrical contact is established in this manner. Specifically, it may be the case that the edge of the memory card is not properly seated in the connector. Alternatively, dust or other contaminants may have accumulated in a connector that is forced between contacts of the memory card and contacts of the connector, resulting in a discontinuity. Also, it may be case that multiple contacts of the memory card come into electrical contact with a single contact of the connector when the memory card is improperly seated. Also, solder joints and other components on the memory card that route signals from the connector may be faulty. In any event, these conditions and other conditions not discussed herein may result in a fault that creates errors during write and read operations involving the memory in the respective memory card.

### BRIEF DESCRIPTION OF THE SEVERAL VIEWS OF THE DRAWINGS

The invention can be understood with reference to the following drawings. The components in the drawings are not necessarily to scale. Also, in the drawings, like reference numerals designate corresponding parts throughout the several views.

FIG. 1 is a block diagram of a server that incorporates interconnect testing according to various embodiments of the present invention;

FIG. 2 is a block diagram of a portion of the server of FIG. 1 according to various embodiments of the present invention;

FIG. 3 is a drawing of a memory card inserted into a slot of the server of FIG. 1, thereby forming interconnects that may be tested according to various embodiments of the present invention;

FIG. 4 is a schematic of an example of a bypass circuit employed in a memory card of the server of FIG. 1 that facilitates interconnect testing according to an embodiment of the present invention;

FIG. 5 is a schematic of another example of a bypass circuit employed in a memory card of the server of FIG. 1 that facilitates interconnect testing according to an embodiment of the present invention; and

FIG. 6 is a schematic of still another example of a bypass circuit employed in a memory card of the server of FIG. 1 that facilitates interconnect testing according to an embodiment of the present invention.

### DETAILED DESCRIPTION

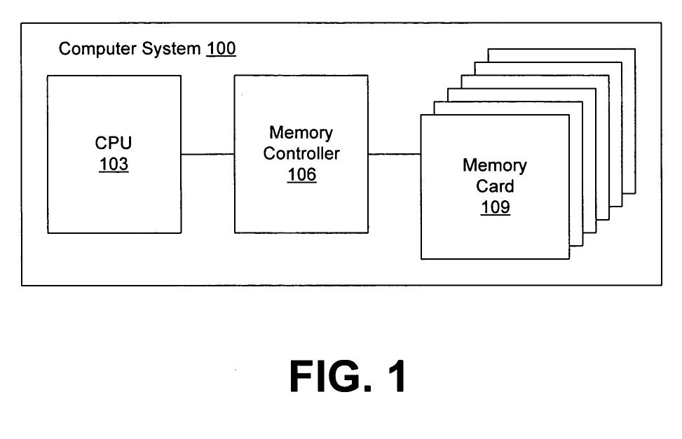

With reference to FIG. 1, shown is a computer system 100 that is configured to detect memory card installation defects according to an embodiment of the present invention. In one embodiment, the computer system 100 may comprise, for example, a server or other system. The computer system 100 includes a central processor unit (CPU) 103, a memory controller 106, and a number of memory cards 109. In addition, while the following discussion references memory cards 109, it is understood that the memory cards 109 may be replaced with any appropriate subsystem or module that performs other functions beyond that of data storage, etc. The memory cards 109 may include a number of random access memory (RAM) components or integrated circuits. In one embodiment, such random access memory (RAM) may comprise dynamic random access memory (DRAM) or other types of memory. While as single memory controller 106 is shown, it is understood that multiple memory controllers 106 may be in data communication with the CPU 103, where each memory controller 106 services multiple memory cards 109.

The computer system 100 may be employed for a number of functions that require significant random access memory (RAM) resources. In this respect, there may be many memory cards 109 employed in conjunction with the operation of the computer system 100. For example, the number of memory cards 109 may be greater than 1000 cards for expansive systems. Each of the memory cards 109 may comprise, for example, a dual in-line memory module (DIMM), a single in-line memory module (SIMM), or other type of memory card. The memory cards 109 may be plugged into connectors on a cell board, motherboard, or other circuit board of the computer system 100 as can be appreciated. The CPU 103 accesses random access memory (RAM) or other memory components on the memory cards 109 by writing data to or reading data to such memory components.

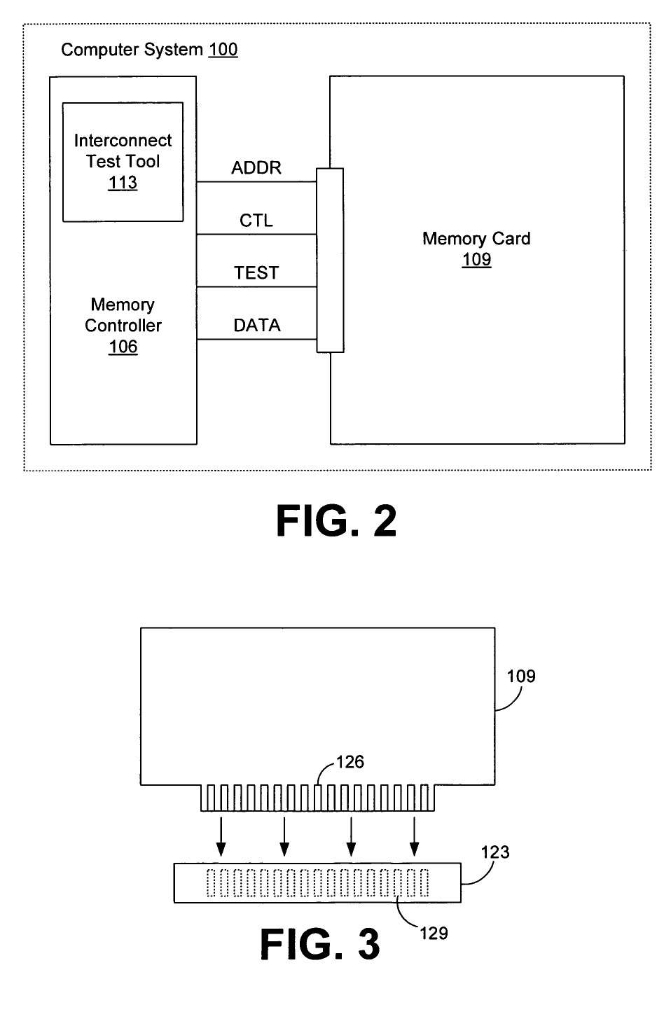

Referring next to FIG. 2, shown is one example of the computer system 100 that draws attention to an example of the memory controller 106 and the memory card 109 according to an embodiment of the present invention. The memory controller 106 is coupled to the memory card 109, for example, by way of an address bus ADDR, a control bus CTL, and a data bus DATA. In various embodiments, the memory controller 106 is also coupled to the memory card 109 using at least one test conductor TEST. In addition, other conductors may be coupled between the memory controller 106 and the memory cards 109.

An interconnect test tool 113 is stored and executed in the memory controller 106. In this respect, the memory controller 106 may comprise a processor circuit having a processor and a memory, where the interconnect test tool 113 is implemented in terms of software or firmware. The interconnect test tool may be based on the boundary scan standard set forth by the Institute of Electrical and Electronics Engineers (IEEE). Alternatively, the memory controller 106 and the interconnect test tool 113 may be implemented in terms of hardware such as digital logic circuitry, or a combination of a processor circuit and software/firmware, and hardware, etc. The interconnect test tool 113 is executed to detect a defect in the installation of the one or more memory cards 109 as will be discussed. Alternatively, the interconnect test tool 113 may be executed by the CPU 103 (FIG. 1) or other circuitry as can be appreciated.

Referring next to FIG. 3, shown is one example of a memory card 109 that is inserted into a receptacle 123. The memory card 109 includes a number of contacts 126 that mate up with contacts 129 in the receptacle 123. Each mated pair of contacts 126 and 129 form an interconnect. Each of the interconnects facilitates, for example, the connection of one of the conductors of the address bus ADDR (FIG. 2), control bus CTL (FIG. 2), the data bus DATA (FIG. 2) or, where applicable, at least one test conductor TEST, to corresponding conductors on the memory card 109.

When the contacts 126 of the memory card 109 are inserted into the receptacle 123, sometimes it is the case that the respective contacts 126 and 129 fail to make good electrical contact, thereby resulting in a fault that prevents full data communication between the memory controller 126 and the respective memory card 109.

Specifically, the fault may exist in the conductors associated with the address bus ADDR, the control bus CTL, the data bus DATA, a test conductor TEST (where applicable), or other busses or conductors, etc. The faults may be due to the fact, for example, that the contacts 126 of the memory card 109 fail to line up properly with the contacts 129 of the receptacle 123, thereby resulting in a discontinuity or a short between adjacent contacts. Also, dust or other particulate matter may have been deposited over the contacts 129 of the receptacle 123 and become wedged between the contacts 126 of the memory card 109 and the contacts 129 of the receptacle 123 when the memory card 109 is inserted into the receptacle 123, thereby preventing good electrical contact. In addition, other reasons may exist as to why a failure of good electrical contact occurs when the memory card 109 is inserted into the receptacle 123. The interconnect test tool 113 is executed in order to detect such faults.

Referring back to FIG. 1, next a discussion of the operation of the interconnect test tool 113 is provided that illustrates how the interconnect test tool 113 detects a fault in one or more interconnects between a given memory card 109 and a receptacle 123 (FIG. 2) into which the memory card 109 has been inserted. In one embodiment, the interconnect test tool 113 first generates a test data value that is to be applied to a respective one of the memory cards 109 through the various interconnects of the contacts 126 and 129 (FIG. 2). In applying the test data value to the respective one of the memory cards 109, the interconnect test tool 113 tracks which one of the memory cards 109 is being tested so that a user may be informed of the precise memory card 109 that needs to be replaced or repaired should a fault be detected.

Next, the test data value is transmitted by the interconnect test tool 113 to the memory card 109. In one embodiment, the test data value is transmitted through a first set of the interconnects between the memory card 109 and the receptacle 123. In one embodiment, the first set of interconnects may be, for example, the interconnects associated with the address bus ADDR and control bus CTL, etc. The test data value is received on the input pins on the memory card 109 as a “received data value”. If no defects exist in the first set of interconnects, then the received data value should be the same as the test data value. On the other hand, if defects exist in the first set of interconnects, the received data value may differ from the test data value.

Once the received data value is obtained, the memory card 109 includes circuitry that relays the received data value from the first set of interconnects to a second set of the interconnects. In so relaying the received data value, the circuitry bypasses one or more memory components such as DRAMs on the memory card 109. The received data value is then transmitted to the interconnect test tool 113 from the memory card 109 via the second set of interconnects. The interconnect test tool 113 receives a “return data value” from the memory card 109. In this respect, the return data value is the received data value as transmitted via the second set of interconnects. If no defect exists in any of the interconnects in the second set, then the return data value should equal the received data value.

Next, the interconnect test tool 113 detects whether a defect exists in one of the interconnects based upon the test data value and the return data value. This may be done by performing a comparison between the test data value and the return data value. For example, if the test data value does not equal the return data value, then it may be assumed that at least one bit of the test data value was changed at some point during the test operation. Such an anomaly may be due to a fault in one of the interconnects. In order to determine precisely which interconnect of the first and second sets of interconnects has experienced a fault, specific data values may be generated for the test data value. For example, assuming that the first set of interconnects is 8 bits wide, then the test data value may range as follows: 00000001, 00000010, 00000100, 00001000, 00010000, 00100000, 01000000, and 10000000. If a value of “1” transmitted in the test data value has changed to a “0” in the return data value, then such is an indication that the corresponding interconnects in the first and/or second sets of interconnects have experienced a fault of some kind. Also, if the test data value has a single “1”, and the return data value has multiple 1's, particularly if the 1's are adjacent to each other, such may indicate that interconnects might be intermingled (i.e. a single contact in a receptacle has come into contact with two contacts from a plug because the plug is misaligned with the receptacle, etc.).

Many different test patterns can be applied to the memory card 109 interface. Analysis of the return data values versus the test data values can identify which contacts or signals contain faults. Given the fact that a fault exists in any one of the interconnects, data corruption is potentially inevitable at some point. Consequently, it may be necessary to reseat, replace, or repair the memory card 109.

If a fault has been detected, then the interconnect test tool 113 indicates that a fault exists in one of the interconnects by generating an appropriate output that is rendered on appropriate output device such as a display device to inform a user that a fault exists. In this respect, the interconnect test tool 113 tracks the location or designation of the particular memory card 109 so that it can provide an indication as to which specific memory card 109 has experienced the fault. Alternatively, the indication as to which memory card 109 has experienced a fault may be rendered on output devices other than a display device such as, for example, a printer, or indicator lights that will indicate whether and where a fault exists.

As described above, the installation defect detection tool 113 provides an advantageous approach to employ in testing the interconnects. Specifically, the exact memory card 109 with which a fault or defect is associated is isolated from a plurality of memory cards 109 in a memory card bank, and is thus identified for a user. This eliminates the necessity of having to replace the memory cards 109 within the memory card bank one at a time to determine where the fault or defect has occurred by trial and error, thereby saving significant amounts of time. This process is a structural test focused at a specific part of a system. It requires less overhead and resources than functional test processes that depend on a certain degree of functionality from the system.

In addition, the memory card 109 may operate in one of two states. In a first state of operation, the received data value is applied to at least one memory on the memory card 109. This is generally the normal operation of the memory card 109. In a second state of operation, the received data value is relayed to the second set of interconnects to be transmitted back to the interconnect test tool 113 and received as the return data value. In the second state of operation, DRAM outputs are blocked or disabled so that they do not interfere with the data being sent back to the interconnect test tool 113 via the second set of interconnects. Given that the memory card 109 includes two states of operation, the memory card 109 is transitioned from the first state of operation to the second state of operation in order to test an electrical connectivity of the interconnects. After the testing of the interconnects is complete, the memory card 109 is transitioned back to the first state of operation. The transition between the first and second states may be implemented by applying a test signal from the interconnect test tool 113 to a control circuit associated with the respective memory card 109. In response to the test signal, the control circuit transitions the memory card 109 from the first state of operation to the second state of operation for testing. A second signal may be employed to transition the memory card 109 back to the first state of operation.

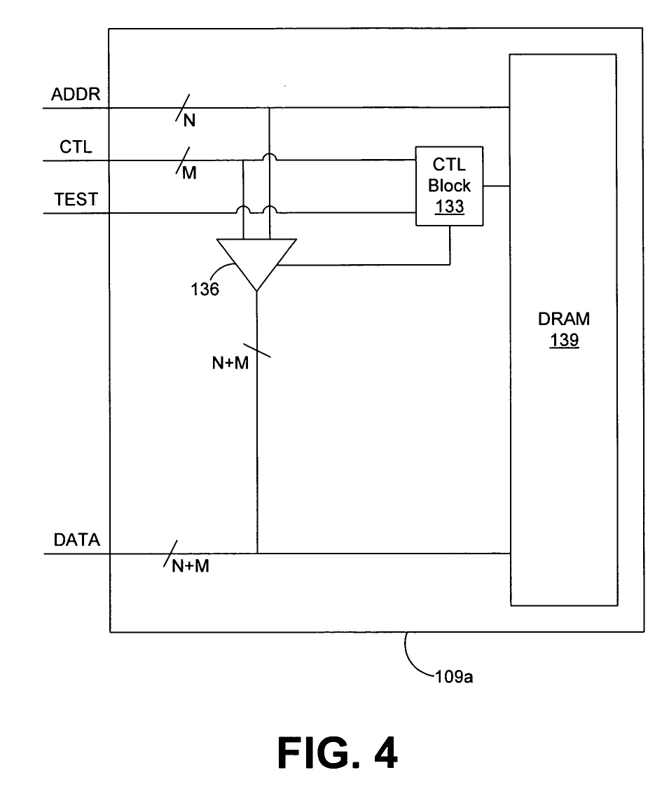

Referring next to FIG. 4, shown is one example of the memory card 109, denoted herein as memory card 109a, according to an embodiment of the present invention. The memory card 109a includes a control block 133, a parallel tri-state device 136, and a dynamic random access memory 139. The dynamic random access memory 139 may comprise a number of memory circuits or semiconnector chips as can be appreciated. The control block 133 receives the control bus CTL and the test conductor TEST as inputs and applies a corresponding output to the dynamic random access memory 139. Also, the control block 133 applies a control output to a control input of the parallel tri-state device 136. The address bus ADDR and the control bus CTL are each applied as inputs to the parallel tri-state device 136. The address bus is N conductors wide and the control bus is M conductors wide. The output of the parallel tri-state device 136 is N+M conductors wide. The output of the parallel tri-state device 136 is coupled to the data bus DATA which is N+M conductors wide as shown. The parallel tri-state device 136 is one that either isolates the address bus ADDR and the control bus CTL from the data bus DATA, or passes through the values from the address bus ADDR and the control bus CTL to the data bus DATA, depending upon whether the parallel tri-state device 136 is enabled as can be appreciated.

The memory card 109a operates as follows. First, the state of the signal on the test conductor TEST controls the control block 133. Specifically, when the test conductor TEST communicates a test signal in a first state, the control block 133 applies the data value received on the control bus CTL directly to the dynamic random access memory (DRAM) 139. In this respect, the control bus inputs received by the DRAM 139 are employed to operate the DRAM 139. For example, the control bus inputs may be employed to provide for writing to or reading from the DRAM 139. Also, the control bus inputs may be employed to enable or disable the DRAM 139 to allow the DRAM 139 to be bypassed as will be discussed.

While the control bus CTL is passed on to the DRAM 139 by the control block 133, a disable signal is applied to the parallel tri-state device 136 to prevent the values on the address and the control busses from being applied to the data bus as shown. This particular state is an operational state in which data is written to or read from the DRAM 139 as can be appreciated.

Assuming that the test signal on the test conductor TEST indicates that the memory card 109a is to be placed in a mode of operation in which the DRAM 139 is bypassed so as to be able to test the interconnects of the memory card 109a, then the control block 133 applies control inputs from the control bus CTL to the DRAM 139 that cause the DRAM 139 not to perform any write operations and not to drive any data on the data bus DATA. In this respect, the control inputs from the control block 133 to the DRAM 139 will cause the DRAM 139 to deactivate. Also, the control block 133 will apply an enable signal to the parallel tri-state device 136. In this respect, the values received by way of the address bus ADDR and the control bus CTL are applied directly to the data bus DATA. Plus, the data received by way of the first set of interconnects associated with the address bus and control bus ADDR and CTL are applied to a second set of interconnects associated with the data bus DATA. In this respect, the memories such as the DRAM 139 are bypassed and the data values are routed from the address and control busses to the data bus as shown.

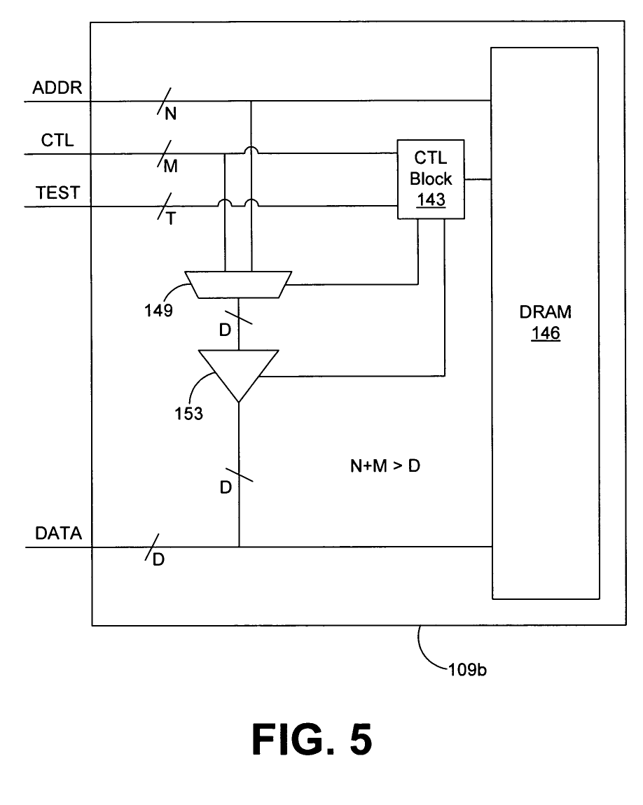

With reference next to FIG. 5, shown is another example of the memory card 109, denoted herein as memory card 109b, according to an embodiment of the present invention. The memory card 109b includes a control block 143, a dynamic random access memory (DRAM) 146, a multiplexer 149, and a parallel tri-state device 153. The address and control bus ADDR and CTL are received as inputs to the memory card 109b. The address bus ADDR is applied to the DRAM 146 and is N conductors wide. The control bus CTL is applied to the control block 143 is M conductors wide. A test bus TEST is applied as an input to the control block 143 and is T conductors wide.

The address and control busses ADDR and CTL are both applied as inputs to the multiplexer 149. The multiplexer 149 is a parallel multiplexer in that it selects between parallel inputs as can be appreciated. The output of the multiplexer 149 is D conductors wide and is applied as an input to the parallel tri-state device 153. The output of the parallel tri-state device 153 is applied to the data bus DATA that is also D conductors wide. In this memory card 109b, D is less than the quantity equal to N+M. As such, the number of conductors of the data bus DATA will not accommodate each of the inputs from the address and control busses ADDR and CTL. As such, the inputs from the address and control busses ADDR and CTL that are received through corresponding interconnects associated with such busses cannot be directly relayed to the data bus on a one to one basis.

Accordingly, the multiplexer 149 will switch between the address and control busses ADDR and CTL as inputs to the various conductors of the data bus DATA. The interconnect test tool 113 may be configured to apply values on the test bus TEST to provide appropriate control inputs that cause the control block 143 to switch between one of two states to select either the address bus ADDR or the control bus CTL to be applied to the tri-state device 153. Alternatively, the selection may be between a first and second set of the total conductors that make up both the address and control busses ADDR and CTL.

Also, depending on the state of the test conductors of the test bus TEST, the control block 143 applies the values on the control bus CTL directly to the DRAM 146 or causes the DRAM 146 to deactivate. Also, the control block 143 applies control inputs to the multiplexer 149 and the tri-state device 153 in order to provide for proper selection of the inputs of the multiplexer 149 to be applied to the tri-state device 153 and to enable the tri-state device 153 to drive the outputs onto the data bus as described.

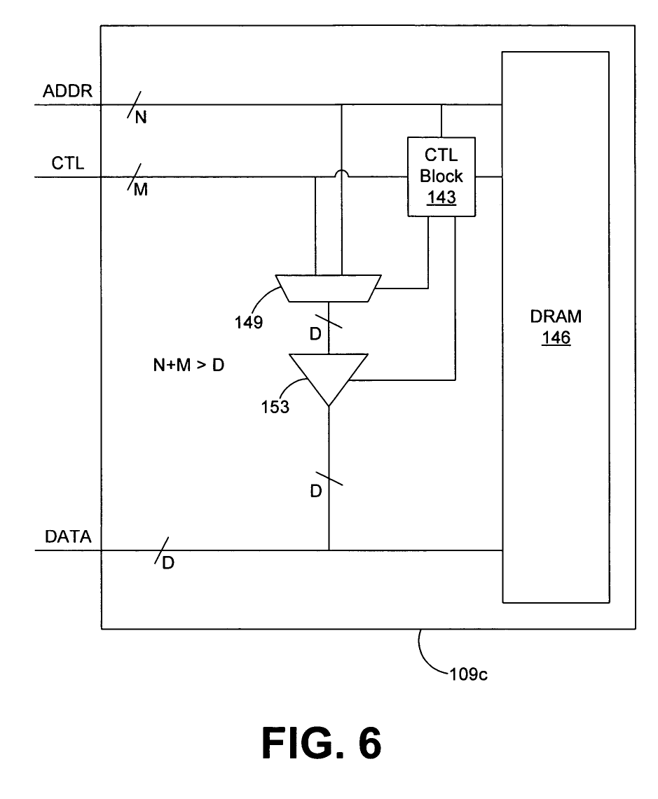

Next, referring to FIG. 6, shown is a memory card 109, denoted herein as memory card 109c, according to an embodiment of the present invention. The memory card 109c is similar to the memory card 109b (FIG. 5) with the exception that the test bus is eliminated. Specifically, inputs received by the control block 143 from the address bus ADDR and control bus CTL control the state of the control block 143 and determine whether the control block 143 will provide all control inputs to the RAM 146 for normal operation or whether the DRAM 146 is bypassed by virtue of the operation of the multiplexer 149 and the parallel tri-state device 153 as was described with reference to FIG. 5. In this respect, a unique value for the address and control busses may be determined that would enable and control the operation of the control block 143. Specifically, multiple unique values transmitted over the combination of the address bus ADDR and the control bus CTL may not only control which state of operation the memory card 109c is in, but may also control the state of the multiplexer 149 and the state of the tri-state device 153.

In addition, in other embodiments, the present invention provides for a method for testing data interconnects. In this embodiment, the method comprises the steps of transmitting a test data value from an interconnect test tool to a memory card included in a memory card bank through a first set of interconnects, relaying a received data value received by the memory card through the first set of interconnects to a second set of interconnects, receiving a return data value in the interconnect test tool from the memory card via the second set of interconnects, and detecting an existence of a defect in one of the interconnects based upon the test data value and the return data value.

In one embodiment of the present method, the received data value bypasses a memory component on the memory card when relayed from the first set of interconnects to the second set of interconnects. Also, the memory card comprises a first state of operation in which the received data value is applied to at least one memory on the memory card and a second state of operation in which the received data value is relayed to the second set of interconnects. In this respect, the method further comprises the step of transitioning the memory card from the first state of operation to the second state of operation in order to test an electrical connectivity of the interconnects.

In still another embodiment, the method further comprises the step of applying a test signal from the interconnect test tool to a control circuit associated with the memory card, wherein the control circuit transitions the memory card from the first state of operation to the second state of operation in response to a state of the test signal. Also, in another embodiment, the second set of interconnects is less than the first set of interconnects, wherein a step of relaying the received data value received by the memory card through the first set of interconnects to the second set of interconnects further comprises the step of multiplexing portions of the received data value received through the first set of interconnects for transmission through the second set of interconnects.

In still other embodiments, the test data value is transmitted from the interconnect test tool to the memory card through a control bus or through an address bus. Also, the return data value is transmitted from the memory card to the interconnect test tool via a data bus.

Although the invention is shown and described with respect to certain embodiments, it is obvious that equivalents and modifications will occur to others skilled in the art upon the reading and understanding of the specification. The present invention includes all such equivalents and modifications, and is limited only by the scope of the claims.

What is claimed is:

1. A method for testing data interconnects, comprising the steps of:
transmitting a test data value from an interconnect test tool to a memory card included in a memory card bank through a first set of interconnects;
relaying a received data value received by the memory card through the first set of interconnects to a second set of interconnects;
receiving a return data value in the interconnect test tool from the memory card via the second set of interconnects; and
detecting an existence of a defect in one of the interconnects based upon the test data value and the return data value.

2. The method of claim 1, further comprising the step of isolating the memory card associated with the defect from a plurality of memory cards in the memory card bank.

3. The method of claim 1, wherein the received data value bypasses a memory component on the memory card when relayed from the first set of interconnects to the second set of interconnects.

4. The method of claim 1, wherein the memory card comprises a first state of operation in which the received data value is applied to at least one memory on the memory card and a second state of operation in which the received data value is relayed to the second set of interconnects, the method further comprising the step of transitioning the memory card from the first state of operation to the second state of operation in order to test an electrical connectivity of the interconnects.

5. The method of claim 4, further comprising the step of applying a test signal from the interconnect test tool to a control circuit associated with the memory card, wherein the control circuit transitions the memory card from the first state of operation to the second state of operation in response to a state of the test signal.

6. The method of claim 1, wherein the second set of interconnects is less than the first set of interconnects, wherein the step of relaying the received data value received by the memory card through the first set of interconnects to the second set of interconnects further comprises the step of multiplexing portions of the received data value received through the first set of interconnects for transmission through the second set of interconnects.

7. The method of claim 1, wherein the test data value is transmitted from the interconnect test tool to the memory card through a control bus, the control bus being coupled to the first set of interconnects.

8. The method of claim 1, wherein the test data value is transmitted from the interconnect test tool to the memory card through an address bus, the address bus being coupled to the first set of interconnects.

9. The method of claim 1, further comprising the step of transmitting the return data value from the memory card to the interconnect test tool via a data bus, the data bus being coupled to the second set of interconnects.

10. A system for testing data interconnects, comprising:
an interconnect test tool in data communication with at least one memory card in a memory card bank, the memory card comprising circuitry that relays a received data value received by the memory card through a first set of interconnects to a second set of interconnects, the interconnect test tool comprising:
logic that transmits a test data value to the memory card through the first set of interconnects; and
logic that detects an existence of a defect in one of the interconnects based upon the test data value and a return data value received from the memory card via the second set of interconnects.

11. The system of claim 10, wherein the memory card associated with the defect is isolated from a plurality of memory cards in the memory card bank.

12. The system of claim 10, further comprising a memory component on the memory card, wherein the received data value bypasses the memory component on the memory card when the circuitry relays the received data value from the first set of interconnects to the second set of interconnects.

13. The system of claim 10,
wherein the memory card comprises a first state of operation in which the received data value is applied to at least one memory on the memory card and a second state of operation in which the received data value is relayed to the second set of interconnects; and
the memory card further comprises control circuitry that transitions the memory card from the first state of operation to the second state of operation in order to test an electrical connectivity of the interconnects.

14. The system of claim 13, further comprising at least one test conductor facilitating the communication of a test signal from the interconnect test tool to the control circuitry, wherein the control circuitry transitions the memory card from the first state of operation to the second state of operation in response to a state of the test signal.

15. The system of claim 10, wherein the second set of interconnects is less than the first set of interconnects, the system further comprising a multiplexer that multiplexes portions of the received data value received through the first set of interconnects for transmission through the second set of interconnects.

16. The system of claim 10, wherein at least a portion of the first set of interconnects is coupled to a control bus, wherein the control bus is employed to transmit at least a portion of the test data value from the interconnect test tool to the memory card.

17. The system of claim 10, wherein at least a portion of the first set of interconnects is coupled to an address bus, wherein the address bus is employed to transmit at least a portion of the test data value from the interconnect test tool to the memory card.

18. The system of claim 10, wherein at least a portion of the second set of interconnects is coupled to a data bus that is employed to transmit the return data value from the memory card to the interconnect test tool.

19. A system for testing data interconnects, comprising:
an interconnect test tool in data communication with at least one memory card in a memory card bank;
the memory card comprising means for relaying a received data value received by the memory card through a first set of interconnects to a second set of interconnects; and
the interconnect test tool comprising:
means for transmitting a test data value to the memory card through the first set of interconnects; and
means for detecting an existence of a defect in one of the interconnects based upon the test data value and a return data value received from the memory card via the second set of interconnects.

20. The system of claim 19, wherein the memory card associated with the defect is isolated from a plurality of memory cards in the memory card bank.

21. The system of claim 19, further comprising a memory component on the memory card, wherein the received data value bypasses the memory component on the memory card when the circuitry relays the received data value from the first set of interconnects to the second set of interconnects.

22. The system of claim 19,
wherein the memory card comprises a first state of operation in which the received data value is applied to at least one memory on the memory card and a second state of operation in which the received data value is relayed to the second set of interconnects; and
the memory card further comprises means for transitioning the memory card from the first state of operation to the second state of operation in order to test an electrical connectivity of the interconnects.

23. The system of claim 22, further comprising at least one test conductor facilitating the communication of a test signal from the interconnect test tool to the control circuitry, wherein means for transitioning the memory card from the first state of operation to the second state of operation operates in response to a state of the test signal.
